(19) United States
(12) Patent Application Publication
(10) Pub. No.: US 2016/0155991 A1
(43) Pub. Date: Jun. 2, 2016

(54) Organic Light-Emitting Component and Method for Producing an Organic Light-Emitting Component

(71) Applicant: OSRAM OLED GmbH, Regensburg (DE)

(72) Inventors: Arndt Jaeger, Regensburg (DE); Andreas Rausch, Regensburg (DE)

(73) Assignees: OSRAM OLED GmbH, Regensburg (DE); OSRAM OLED GmbH, Regensburg (DE)

(21) Appl. No.: 14/900,151

(22) PCT Filed: Jun. 30, 2014
(86) PCT No.: PCT/EP2014/063835

§ 371 Date: Dec. 19, 2015

(30) Foreign Application Priority Data
Jul. 5, 2013 (DE) 10 2013 107 113.9

(51) Int. Cl. H01L 51/52; H01L 51/50; H01L 51/56

(52) U.S. Cl. CPC H01L 51/5278; H01L 51/56; H01L 51/5064; H01L 51/506; H01L 51/5076; H01L 2251/558; H01L 51/0078

(57) ABSTRACT

An organic light-emitting component has a substrate, a first electrode on the substrate, a first organic functional layer stack on the first electrode, a charge carrier generation layer stack on the first organic functional layer stack, a second organic functional layer stack on the charge carrier generation layer stack and a second electrode on the second organic functional layer stack. The charge carrier generation layer stack has at least one hole transport layer, one electron transport layer and one intermediate layer. The at least one intermediate layer includes a multinuclear phthalocyanine derivative.

This patent application is a national phase filing under section 371 of PCT/EP2014/063835, filed Jun. 30, 2014, which claims the priority of German patent application 10 2013 107 113.9, filed Jul. 5, 2013, each of which is incorporated herein by reference in its entirety.

### TECHNICAL FIELD

An organic light-emitting component and a process for producing an organic light-emitting component are specified.

### BACKGROUND

Organic light-emitting components, for example, organic light-emitting diodes (OLEDs), typically have at least one electroluminescent organic layer between two electrodes which are configured as anode and cathode and by means of which charge carriers, i.e., electrons and holes, can be injected into the electroluminescent organic layer. Highly efficient and long-lasting OLEDs can be produced by means of conductivity doping through the use of a p-i-n junction analogously to conventional inorganic light-emitting diodes, as described, for example, in the publication R. Meerheim et al., Appl. Phys. Lett. 89, 061111 (2006). In this case, the charge carriers, i.e., the holes and electrons, are injected from the p- and n-doped layers in a controlled manner into the intrinsic electroluminescent layer, where they form excitons which, on radiative recombination, lead to emission of a photon. The higher the flow initiated, the higher the luminance emitted. However, stress also increases with current and luminance, which shortens the OLED lifetime.

In order to increase the luminance and prolong the lifetime, it is possible to stack a plurality of OLEDs one on top of another in a monolith, in which case they are connected electrically by charge carrier generation layer stacks, called charge generation layers (CGL). A CGL consists, for example, of a highly doped p-n junction which serves as a tunnel junction between the stacked emission layers. CGLs of this kind are described, for example, in M. Kroger et al., Phys. Rev. B 75, 235321 (2007) and T.-W. Lee et al., APL 92, 043301 (2008).

Prerequisites for use of a CGL in a white OLED, for example, are a simple construction, i.e., a small number of easily processible layers, a low voltage drop over the CGL, a minimum change in the voltage drop over the CGL during the operation of the OLED under the operating conditions desired, and maximum transmission in the spectral range emitted by the OLED, in order that absorption losses of the emitted light are avoided.

Known CGLs use inorganic materials for the p-doping, for example, V₂O₅, MoO₃, WO₃, or organic materials, for example, F4-TCNQ, Cu(I)pFBz or Bi(III)pFBz. For the n-doping, organic compounds are used, such as 1,4,5,8,9,11-hexaazatriphenylene, hexacarbonitrile (HAT-CN) or metals having a low work function, for example, Cs, Li and Mg, or compounds thereof (for example, Cs₂CO₃, Cs₃PO₄).

### SUMMARY

Particular embodiments specify an organic light-emitting component. Further embodiments specify a process for producing an organic light-emitting component.

An organic light-emitting component is specified, having a substrate, a first electrode atop the substrate, a first organic functional layer stack atop the first electrode, a charge carrier generation layer stack atop the first organic functional layer stack, a second organic functional layer stack atop the charge carrier generation layer stack, and a second electrode atop the second organic functional layer stack, wherein the charge carrier generation layer stack has at least one hole-transporting layer, an electron-transporting layer and an interlayer, and wherein the at least one interlayer includes a polynuclear phthalocyanine derivative.

Here and hereinafter, “atop” with regard to the arrangement of the layers and layer stacks means a basic sequence and should be understood to mean that a first layer is disposed on a second layer either such that the layers have a common interface, i.e., are in direct mechanical and/or electrical contact with one another, or such that further layers are disposed between the first layer and the second layer.

The organic functional layer stacks may each have layers comprising organic polymers, organic oligomers, organic monomers, organic non-polymeric small molecules or combinations thereof. In addition, they may have at least one organic light-emitting layer. Suitable materials for the organic light-emitting layer are materials having emission of radiation due to fluorescence or phosphorescence, for example, Ir or Pt complexes, polyfluorene, polythiophene or polyphenylene or derivatives, compounds, mixtures or copolymers thereof. The organic functional layer stacks may each additionally have a functional layer configured as a hole transport layer in order to enable effective injection of holes into the at least one light-emitting layer. Advantageous materials for a hole transport layer may be found, for example, to be tertiary amines, carbazole derivatives, camphorsulfonic acid-doped polyaniline or polystyrenesulfonic acid-doped polyethylenedioxythiophene. The organic functional layer stacks may each additionally have a functional layer in the form of an electron transport layer. In addition, the organic functional layer stacks may also have electron and/or hole blocker layers.

With regard to the basic structure of an organic light-emitting component, for example, with regard to the structure, the layer composition and the materials of the organic functional layer stack, reference is made to publication WO 2010/066245 A1, which is hereby explicitly incorporated by reference particularly in relation to the structure of an organic light-emitting component.

The substrate may include, for example, one or more materials in the form of a layer, of a sheet, of a film or a laminate, selected from glass, quartz, plastic, metal and silicon wafer. More preferably, the substrate includes or consists of glass, for example, in the form of a glass layer, glass film or glass plate.

The two electrodes between which the organic functional layer stacks are disposed may, for example, both be translucent, such that the light generated in the at least one light-emitting layer between the two electrodes can be emitted in both directions, i.e., in the direction of the substrate and in the direction facing away from the substrate. In addition, for example, all layers of the organic light-emitting component may be translucent, such that the organic light-emitting component forms a translucent and especially a transparent OLED. In addition, it may also be possible for one of the two electrodes between which the organic functional layer stacks are disposed to be non-translucent and preferably reflective, such that the light generated in the at least one light-emitting layer between the two electrodes can be emitted only in one direction through the translucent electrode. If the electrode disposed on the substrate is translucent and the substrate is also translucent, this is also referred to as a “bottom emitter”, whereas, if the electrode disposed so as to face away from the substrate is translucent, this is referred to as a “top emitter”.

The first and second electrodes may independently include a material selected from a group comprising metals, electrically conductive polymers, transition metal oxides and transparent conductive oxides (TCOs). The electrodes may also be layer stacks of two or more layers of the same or of different metals or of the same or different TCOs.

Suitable metals are, for example, Ag, Pt, Au, Mg, Al, Ba, In, Ca, Sm or Li, or compounds, combinations or alloys thereof.

Transparent conductive oxides (“TCOs” for short) are transparent conductive materials, generally metal oxides, for example, zinc oxide, tin oxide, cadmium oxide, titanium oxide, indium oxide or indium tin oxide (ITO). As well as binary metal-oxygen compounds, for example, ZnO, SnO₂ or In₂O₃, the group of the TCOs also includes ternary metal-oxygen compounds, for example, Zn₂SnO₄, CdSnO₃, ZnSnO₃, MgIn₂O₄, GaInO₃, Zn₂In₂O₅ or In₄Sn₃O₁₂ or mixtures of different transparent conductive oxides. In addition, the TCOs do not necessarily correspond to a stoichiometric composition and may also be p- or n-doped.

The organic functional layer stacks of the organic light-emitting component described here additionally have a directly adjoining charge carrier generation layer stack. Here and hereinafter, a “charge carrier generation layer stack” describes a layer sequence which takes the form of a tunnel junction and which is generally formed by a p-n junction. The charge carrier generation layer stack, which can also be referred to as “charge generation layer” (CGL), especially takes the form of a tunnel junction which can be used for effective separation of charge and hence for “generation” of charge carriers for the adjoining layers.

For example, the charge carrier generation layer stack may directly adjoin the organic functional layer stack.

The hole-transporting layer of the charge carrier generation layer stack may also be referred to as p-conducting layer, and the electron-transporting layer as n-conducting layer. The interlayer of the charge carrier generation layer stack may also be referred to as diffusion barrier layer in accordance with its function. It may include or consist of a polynuclear phthalocyanine derivative.

Polynuclear phthalocyanine derivatives are obtained by fusion, i.e., joining by benzene rings of two or more mononuclear phthalocyanine derivatives or phthalocyanine units. The fusion allows the photophysical properties of phthalocyanine molecules to be altered in a controlled manner, maintaining a high chemical stability. This makes it possible to influence the emitted spectrum of the organic light-emitting component. More particularly, as compared with mononuclear phthalocyanines, it is possible to shift the long-wave absorptions from the yellow/red to the infrared spectral region by increasing the size of the chromophore system, i.e., delocalization over the entire molecular structure. The high-energy transitions in the near UV range, in contrast, are unaffected by the fusion and thus do not lead to any absorption losses in the visible region. The resulting molecules of increased size, like the mononuclear phthalocyanine, are very stable and have good aggregation, meaning that they are vapor-deposited like flakes on the substrate.

In the case of mononuclear phthalocyanines, the extent of the π electron system is restricted to the monomeric phthalocyanine skeleton. Illustrative mononuclear phthalocyanines are shown in the structural forms I to III, the formulae I and II being in oxidized form. Structural formula I shows the phthalocyanine VOPc, structural formula II shows the phthalocyanine TiOPc and structural formula III shows the phthalocyanine ZnPc.

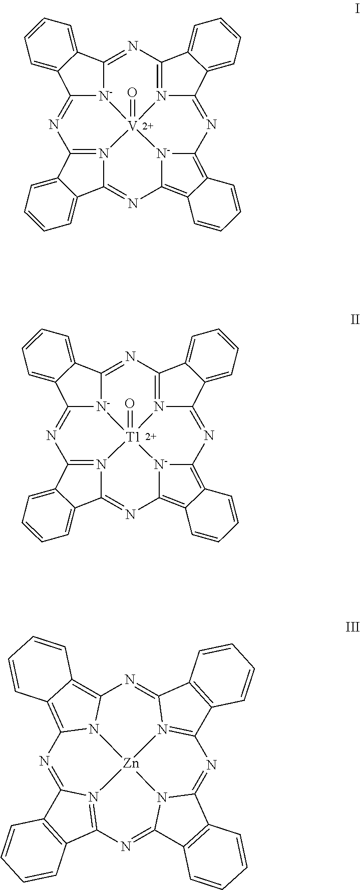

The fusion of the monomer units results in chemical coupling of these. The result is an extension of the π electron system and a stabilization of the low-energy electronic states characterized by a shift in the absorption peak from the yellow/red to the infrared spectral region.

In the case of use of a fused polynuclear phthalocyanine derivative in the interlayer of the charge carrier generation layer stack, there is thus reduced absorption in the spectral region emitted by the organic functional layer stack, which results in an increased efficiency of the component. This advantage is obtained with simultaneously unchanged stability of the charge carrier generation layer stack compared to mononuclear phthalocyanines.

The polynuclear phthalocyanine derivative may contain a metal or a metal compound. It is thus possible for each phthalocyanine unit in the polynuclear phthalocyanine derivative to have one or more chemical bonds to one metal or one metal compound in each case and/or for each phthalocyanine unit in the polynuclear phthalocyanine derivative to be coordinated to a metal or a metal compound. The metal or metal compound selected may be materials selected from a group comprising Cu, Zn, Co, Al, Ni, Fe, SnO, Mn, Mg, VO and TiO. This means that the phthalocyanine derivative may be in oxidized form when a metal oxide is used. The oxidation may stabilize the phthalocyanine derivative with respect to the nonoxidized form. In a further embodiment, the polynuclear phthalocyanine derivative may also be free of metal.

The polynuclear phthalocyanine derivative may be a dinuclear phthalocyanine derivative. One example of a metal-free dinuclear phthalocyanine derivative is shown in structural formula IV:

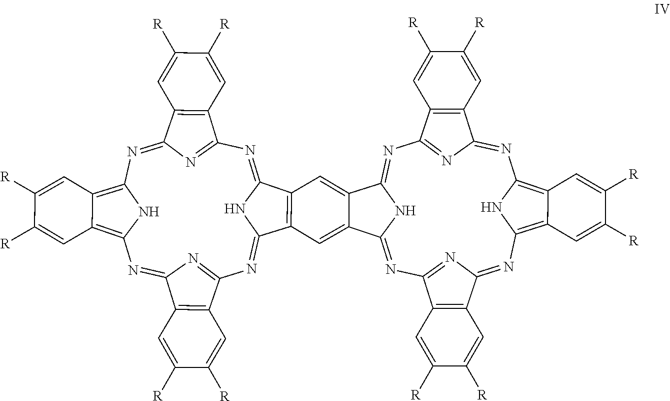

This is H₂Pc-H₂Pc. The R radicals in the structural formula IV may each independently be selected from: branched or unbranched alkyl radicals, for example, methyl, ethyl, t-butyl or isopropyl radicals, and aromatic radicals, for example, phenyl radicals.

One example of a metalated dinuclear phthalocyanine derivative is shown in the structural formula V:

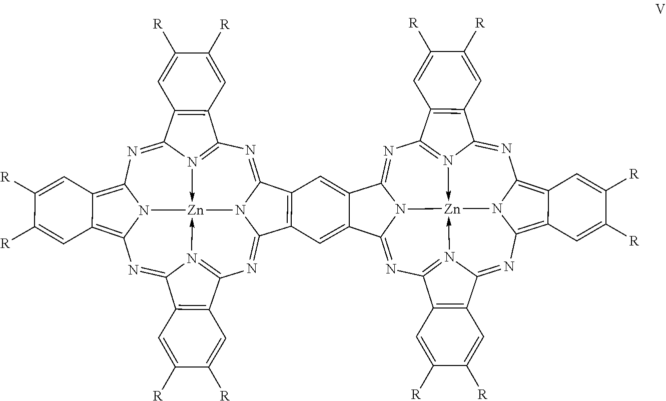

This is ZnPc-ZnPc. The R radicals may be selected as specified for structural formula IV.

The polynuclear phthalocyanine derivative may be a tri- or tetranuclear phthalocyanine derivative. The tri- or tetranuclear phthalocyanine derivative may comprise phthalocyanine derivatives fused to one another in linear form or at right angles. One example of a linear trinuclear phthalocyanine derivative is shown in structural formula VI for the example of a zinc-containing phthalocyanine derivative:

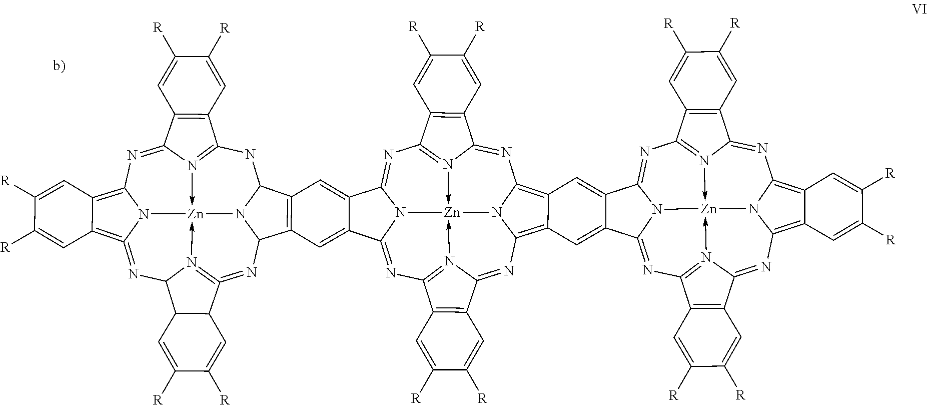

The structural formula VII shows a trinuclear zinc-containing phthalocyanine fused at right angles:

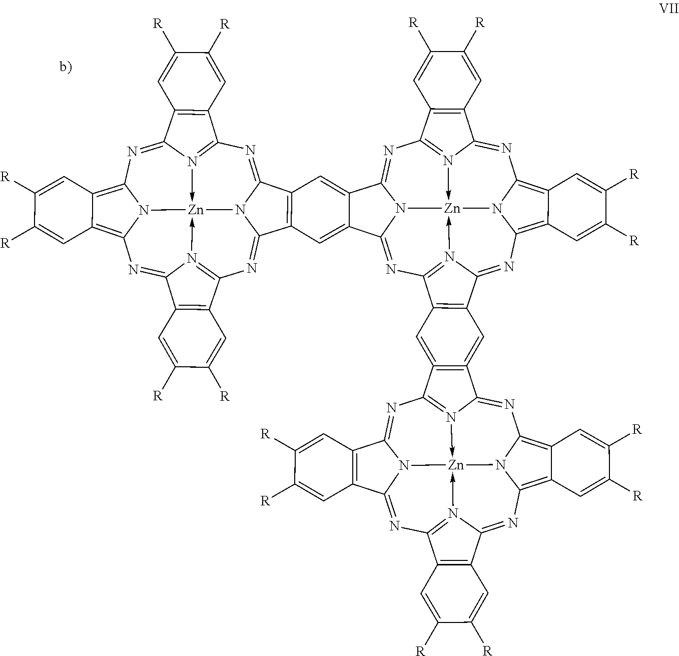

The R radicals in the structural formulae VI and VII may be selected as specified for the structural formula IV. Polynuclear phthalocyanine derivatives having five or more phthalocyanine units are likewise conceivable.

The interlayer including or consisting of the polynuclear phthalocyanine derivative may have a thickness selected from a range comprising 1 to 50 nm, especially 2 nm to 10 nm. The thickness of the interlayer may especially be about 4 nm. Interlayers including or consisting of polynuclear phthalocyanine derivatives may be particularly thick, since the use of the polynuclear phthalocyanine derivative causes a low level of absorption losses to occur. This applies both to metal-free and metalated fused polynuclear phthalocyanine derivatives. The thicker the intermediate layer, the better the separation of the n and p sides achievable, i.e., the better the separation of the hole-transporting layer and the electron-transporting layer of the charge carrier generation layer stack.

The transmission of the polynuclear phthalocyanine derivatives in the visible wavelength range, i.e., between about 400 and 700 nm, is advantageously increased as compared with the CuPc, H₂Pc, ZnPc, CoPc, SnOPc, VOPc, TiOPc or NET-39 materials used to date. This reduces the residual absorption in the organic light-emitting component specifically in the yellow/red region, which makes up the main proportion of the radiation emitted in the case of white OLEDs, for example. The OLED efficiency can consequently be increased. Especially in organic light-emitting components with internal emission, because of the multiple reflections that occur here, a reduction in residual absorption in the organic layers is crucial to achieve high efficiencies.

Since the monomeric phthalocyanine derivatives or units are joined to one another by rigid benzene rings, the polynuclear phthalocyanine derivatives have excellent morphology in the interlayer and are superior in terms of their aggregation properties in thin films to smaller molecules, for example, monomeric phthalocyanine derivatives. In the case of use of fused polynuclear phthalocyanine derivatives, it is thus possible to achieve thinner interlayers with equal stability than with known monomer units, which leads to a reduction of absorption and stress losses.

The hole-transporting layer may be disposed atop the interlayer, which is in turn disposed atop the electron-transporting layer.

The hole-transporting layer of the charge carrier generation layer stack may further comprise a first hole-transporting layer and a second hole-transporting layer, and the first hole-transporting layer may be disposed atop the electron-transporting layer and the second hole-transporting layer atop the first hole-transporting layer. The interlayer may be disposed between the electron-transporting layer and the first hole-transporting layer and/or between the first hole-transporting layer and the second hole-transporting layer. It is thus possible for either one or two interlayers to be present in the charge carrier generation layer stack and, if only one interlayer is present, this may be present at two different positions.

The hole-transporting layer and the first and second hole-transporting layers may independently be undoped or p-doped. The p-doping may, for example, have a proportion in the layer of less than 10% by volume, especially of less than 1% by volume. The electron-transporting layer may be undoped or n-doped. For example, the electron-transporting layer may be n-doped and the first and second hole-transporting layers may be undoped. In addition, the electron-transporting layer, for example, may be n-doped and the second hole-transporting layer p-doped.

The hole-transporting layer or first and second hole-transporting layers may independently include a material selected from a group comprising HAT-CN, F16CuPc, LG-101, α-NPD, NPB (N,N′-bis(naphthalen-1-yl)-N,N′-bis(phenyl)benzidine), beta-NPB (N,N′-bis-(naphthalen-2-yl)-N,N′-bis(phenyl)benzidine), TPD (N,N′-bis(3-methylphenyl)-N,N′-bis(phenyl)benzidine), spiro-TPD (N,N′-bis(3-methylphenyl)-N,N′-bis(phenyl)-benzidine), spiro-NPB (N,N′-bis(naphthalen-1-yl)-N,N′-bis(phenyl)spiro), DMFL-TPD (N,N′-bis(3-methylphenyl)-N,N′-bis(phenyl)-9,9-dimethylfluorene), DMFL-NPB (N,N′-bis(naphthalen-1-yl)-N,N′-bis(phenyl)-9,9-dimethyl-fluorene), DPFL-TPD (N,N′-bis(3-methylphenyl)-N,N′-bis(phenyl)-9,9-diphenylfluorene), DPFL-NPB (N,N′-bis(naphthalen-1-yl)-N,N′-bis(phenyl)-9,9-diphenyl-fluorene), spiro-TAD (2,2′,7,7′-tetrakis(N,N-diphenylamino)-9,9′-spirobifluorene), 9,9-bis[4-(N,N-bis(biphenyl-4-yl)amino)phenyl]-9H-fluorene, 9,9-bis[4-(N,N-bis(naphthalen-2-yl)amino)phenyl]-9H-fluorene, 9,9-bis[4-(N,N′-bis(naphthalen-2-yl)-N,N′-bisphenyl-amino)phenyl]-9H-fluorine, N,N′-bis(phenanthren-9-yl)-N,N′-bis(phenyl)benzidine, 2,7-bis[N,N-bis(9,9-spiro-bifluoren-2-yl)amino]-9,9-spirobifluorene, 2,2′-bis[N,N-bis(biphenyl-4-yl)amino]-9,9-spirobifluorene, 2,2′-bis(N,N-diphenylamino)-9,9-spirobifluorene, di[4-(N,N-ditolylamino)phenyl]cyclohexane, 2,2′,7,7′-tetra(N,N-ditolyl)aminospirobifluorene, N,N,N′,N′-tetra(naphthalen-2-yl)benzidine and mixtures of these compounds.

The first hole-transporting layer may include or consist of HAT-CN, for example.

If the hole-transporting layer or the first and second hole-transporting layers is/are formed from a substance mixture of matrix and p-dopant, the dopant may be selected from a group comprising MoOₓ, WOₓ, VOₓ, Cu(I)pFBz, Bi(III)pFBz, F4-TCNQ, NDP-2 and NDP-9. Matrix materials used may, for example, be one or more of the above mentioned materials for the hole-transporting layer.

The hole-transporting layer or the first and second hole-transporting layers of the charge carrier generation layer stack may have a transmission greater than 90% within a wavelength range from about 400 nm to about 700 nm, especially within a wavelength range from 450 nm to 650 nm.

The first and second hole-transporting layers may together have a layer thickness within a range from about 1 nm to about 500 nm.

The electron-transporting layer may include a material selected from a group comprising NET-18, 2,2′,2″-(1,3,5-benzenetriyl)tris(1-phenyl-1H-benzimidazole), 2-(4-biphenylyl)-5-(4-tert-butylphenyl)-1,3,4-oxadiazole, 2,9-dimethyl-4,7-diphenyl-1,10-phenanthroline (BCP), 8-hydroxyquinolinolatolithium, 4-(naphthalen-1-yl)-3,5-diphenyl-4H-1,2,4-triazole, 1,3-bis[2-(2,2′-bipyridin-6-yl)-1,3,4-oxadiazol-5-yl]benzene, 4,7-diphenyl-1,10-phenanthroline (BPhen), 3-(4-biphenylyl)-4-phenyl-5-tert-butylphenyl-1,2,4-triazole, bis(2-methyl-8-quinolinolato)-4-(phenylphenolato)aluminum, 6,6′-bis[5-(biphenyl-4-yl)-1,3,4-oxadiazol-2-yl]-2,2′-bipyridyl, 2-phenyl-9,10-di(naphthalen-2-yl)anthracene, 2,7-bis[2-(2,2′-bipyridin-6-yl)-1,3,4-oxadiazol-5-yl]-9,9-dimethylfluorene, 1,3-bis[2-(4-tert-butylphenyl)-1,3,4-oxadiazol-5-yl]benzene, 2-(naphthalen-2-yl)-4,7-diphenyl-1,10-phenanthroline, 2,9-bis(naphthalen-2-yl)-4,7-diphenyl-1,10-phenanthroline, tris(2,4,6-trimethyl-3-(pyridin-3-yl)phenyl)borane, 1-methyl-2-(4-(naphthalen-2-yl)phenyl)-1H-imidazo[4,5-f][1,10]-phenanthroline, phenyldipyrenylphosphine oxides, naphthalenetetracarboxylic dianhydride and imides thereof, perylenetetracarboxylic dianhydride and imides thereof, materials based on siloles having a silacyclopentadiene unit and mixtures of the aforementioned substances comprises.

If the electron-transporting layer is formed from a substance mixture of matrix and n-dopant, the matrix may comprise one of the abovementioned materials of the electron-transporting layer. For example, the matrix may comprise or be NET-18. The n-dopant of the electron-transporting layer may be selected from a group comprising NDN-1, NDN-26, Na, Ca, MgAg, Cs, Li, Mg, Cs₂CO₃ and Cs₃PO₄.

The electron-transporting layer may have a layer thickness within a range from about 1 nm to about 500 nm. In addition, the electron-transporting layer may also comprise a first electron-transporting layer and a second electron-transporting layer.

In addition, the valence band (HOMO=highest occupied molecular orbital) of the material of the electron-transporting layer may be higher than the conduction band (LUMO=lowest unoccupied molecular orbital) of the material of the hole-transporting layer.

In one embodiment, the organic light-emitting component may take the form of an organic light-emitting diode (OLED).

Additionally specified is a process for producing an organic light-emitting component, comprising the process steps of

A) forming a first organic functional layer stack atop a first electrode disposed atop a substrate,

B) forming a charge carrier generation layer stack atop the first organic functional layer stack,

C) forming a second organic functional layer stack atop the charge carrier generation layer stack, and

D) disposing a second electrode atop the second organic functional layer stack. Process step B) here comprises the steps of

B1) applying at least one electron-transporting layer atop the first organic functional layer stack,

B2) applying a first hole-transporting layer or an interlayer atop the electron-transporting layer, and

B3) applying an interlayer atop the first hole-transporting layer and a second hole-transporting layer atop the interlayer or applying a hole-transporting layer atop the interlayer, wherein the applying of the interlayer involves applying a polynuclear phthalocyanine derivative.

The polynuclear phthalocyanine derivative may be applied by vapor deposition or as a solution. The vapor deposition can be effected, for example, at temperatures from the range of 200° C. to 600° C.

In process step B), it is additionally possible in process step B1) to apply an electron-transporting layer, in process step B2) to apply an interlayer atop the electron-transporting layer and a first hole-transporting layer atop the interlayer, and in process step B3) to apply an interlayer atop the first hole-transporting layer and a second hole-transporting layer atop the interlayer or a second hole-transporting layer atop the first hole-transporting layer.

A process described here is especially suitable for production of a component described here, and so all the features described for the process are also disclosed for the component and vice versa.

### BRIEF DESCRIPTION OF THE DRAWINGS

Further advantages, advantageous embodiments and developments will be apparent from the working examples described hereinafter in conjunction with the figures.

FIGS. 1a to 1c show schematic side views of working examples of an organic light-emitting component according to various embodiments,

FIG. 2 shows transmission spectra of interlayer materials,

FIG. 3a shows the schematic side view of a charge carrier generation layer stack,

FIG. 3b shows an energy level diagram of the charge carrier generation layer stack.

In the working examples and figures, elements that are identical, of the same type or equivalent may each be given the same reference numerals. The elements shown and their size ratios relative to one another should not be regarded as being to scale; instead, individual elements, for example, layers, parts, components and areas, may be shown in an excessively large size for better representability and/or for better understanding.

### DETAILED DESCRIPTION OF ILLUSTRATIVE EMBODIMENTS

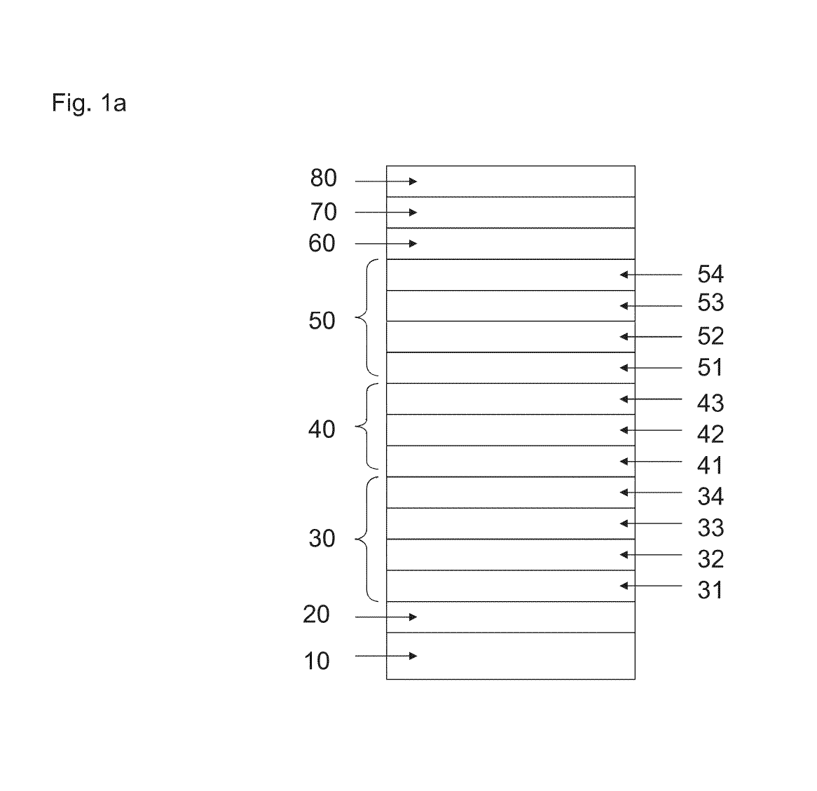

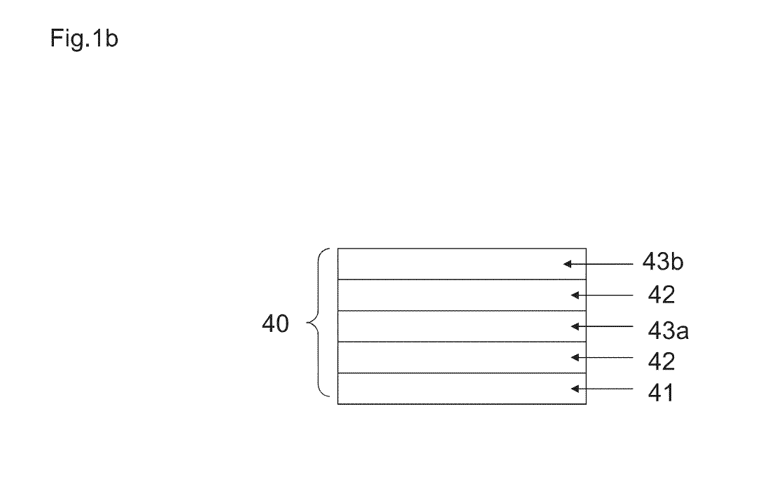

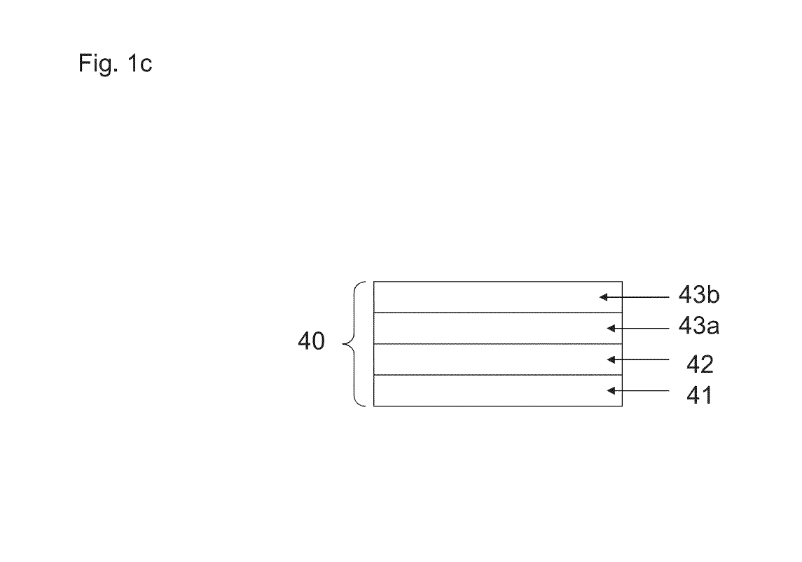

FIG. 1a shows a working example of an organic light-emitting component. The latter has a substrate 10, a first electrode 20, a first organic functional layer stack 30, a charge carrier generation layer stack 40, a second organic functional layer stack 50, a second electrode 60, a thin barrier layer 70 and a cover 80. The first organic functional layer stack 30 comprises a hole injection layer 31, a first hole transport layer 32, a first emission layer 33 and an electron transport layer 34. The second organic functional layer stack 50 comprises a second hole transport layer 51, a second emission layer 52, a second electron transport layer 53 and an electron injection layer 54. The charge carrier generation layer stack 40 comprises an electron-transporting layer 41, an interlayer 42 and a hole-transporting layer 43.

The substrate 10 may serve as carrier element and may be formed, for example, from glass, quartz and/or a semiconductor material. Alternatively, the substrate 10 may also be a polymer film or a laminate composed of two or more polymer films.

The component in FIG. 1a may be set up in various embodiments as a top or bottom emitter. In addition, it may also be set up as a top and bottom emitter, and hence be an optically transparent component, for example, a transparent organic light-emitting diode.

The first electrode 20 may take the form of an anode or cathode and may include ITO, for example, as material. If the component is to be configured as a bottom emitter, substrate 10 and first electrode 20 are translucent. If the component is to be configured as a top emitter, the first electrode 20 may preferably also be reflective. The second electrode 60 takes the form of a cathode or anode and may include, for example, a metal or a TCO. The second electrode 60 may also be translucent when the component is configured as a top emitter.

The thin barrier layer 70 protects the organic layers from damaging materials from the environment, for example, moisture and/or oxygen and/or other corrosive substances, for example, hydrogen sulfide. For this purpose, the thin barrier layer 70 may have one or more thin layers which have been applied, for example, by means of an atom layer deposition process and which include, for example, one or more of the following materials: aluminum oxide, zinc oxide, zirconium oxide, titanium oxide, hafnium oxide, lanthanum oxide and tantalum oxide. The thin barrier layer 70 additionally has mechanical protection in the form of the encapsulation 80 which takes the form, for example, of a polymer layer and/or of a glass layer that has been laminated on, by which means it is possible to achieve scratch protection, for example.

The emission layers 33 and 52 include, for example, an electroluminescent material mentioned in the general section. These may be selected so as to be identical or different. In addition, charge carrier blocker layers (not shown here) may be provided, between which are disposed the organic light-emitting emission layers 33 and 52.

For example, the charge carrier blocker layer present may be a hole blocker layer including a material selected from a group comprising 2,2′,2″-(1,3,5-benzenetriyl)tris(1-phenyl-1H-benzimidazole), 2-(4-biphenylyl)-5-(4-tert-butylphenyl)-1,3,4-oxadiazole, 2,9-dimethyl-4,7-diphenyl-1,10-phenanthroline (BCP), 8-hydroxyquinolinolatolithium, 4-(naphthalen-1-yl)-3,5-diphenyl-4H-1,2,4-triazole, 1,3-bis[2-(2,2′-bipyridin-6-yl)-1,3,4-oxadiazol-5-yl]-benzene, 4,7-diphenyl-1,10-phenanthroline (BPhen), 3-(4-biphenylyl)-4-phenyl-5-tert-butylphenyl-1,2,4-triazole, bis(2-methyl-8-quinolinolato)-4-(phenylphenolato)-aluminum, 6,6′-bis[5-(biphenyl-4-yl)-1,3,4-oxadiazol-2-yl]-2,2′-bipyridyl, 2-phenyl-9,10-di(naphthalen-2-yl)anthracene, 2,7-bis[2-(2,2′-bipyridin-6-yl)-1,3,4-oxadiazol-5-yl]-9,9-dimethylfluorene, 1,3-bis[2-(4-tert-butylphenyl)-1,3,4-oxadiazol-5-yl]-benzene, 2-(naphthalen-2-yl)-4,7-diphenyl-1,10-phenanthroline, 2,9-bis(naphthalen-2-yl)-4,7-diphenyl-1,10-phenanthroline, tris(2,4,6-trimethyl-3-(pyridin-3-yl)phenyl)borane, 1-methyl-2-(4-(naphthalen-2-yl)phenyl)-1H-imidazo[4,5-f][1,10]phenanthroline, phenyldipyrenylphosphine oxide, naphthalenetetracarboxylic dianhydride and imides thereof, perylenetetracarboxylic dianhydride and imides thereof, materials based on siloles having a silacyclopentadiene unit, and mixtures thereof.

In addition, the charge carrier blocker layer present may be an electron blocker layer including a material selected from a group comprising NPB (N,N′-bis(naphthalen-1-yl)-N,N′-bis(phenyl)-benzidine), beta-NPB N,N′-bis(naphthalen-2-yl)-N,N′-bis(phenyl)-benzidine), TPD (N,N′-bis(3-methylphenyl)-N,N′-bis(phenyl)-benzidine), spiro-TPD (N,N′-bis(3-methylphenyl)-N,N′-bis(phenyl)-benzidine), spiro-NPB (N,N′-bis(naphthalen-1-yl)-N,N′-bis(phenyl)-spiro), DMFL-TPD (N,N′-bis(3-methylphenyl)-N,N′-bis(phenyl)-9,9-dimethylfluorene), DMFL-NPB (N,N′-bis(naphthalen-1-yl)-N,N′-bis(phenyl)-9,9-dimethylfluorene), DPFL-TPD (N,N′-bis(3-methylphenyl)-N,N′-bis(phenyl)-9,9-diphenylfluorene), DPFL-NPB (N,N′-bis(naphthalen-1-yl)-N,N′-bis(phenyl)-9,9-diphenylfluorene), spiro-TAD (2,2′,7,7′-tetrakis(N,N-diphenylamino)-9,9′-spirobifluorene), 9,9-bis[4-(N,N-bis(biphenyl-4-yl)amino)phenyl]-9H-fluorene, 9,9-bis[4-(N,N-bis(naphthalen-2-yl)amino)phenyl]-9H-fluorene, 9,9-bis[4-(N,N′-bis(naphthalen-2-yl)-N,N′-bisphenyl-amino)phenyl]-9H-fluorine, N,N′-bis(phenanthren-9-yl)-N,N′-bis(phenyl)benzidine, 2,7-bis[N,N-bis(9,9-spirobifluoren-2-yl)amino]-9,9-spirobifluorene, 2,2′-bis[N,N-bis(biphenyl-4-yl)amino]-9,9-spiro-bifluorene, 2,2′-bis(N,N-diphenylamino)9,9-spirobifluorene, di[4-(N,N-ditolylamino)phenyl]cyclohexane, 2,2′,7,7′-tetra(N,N-ditolyl)aminospirobifluorene, N,N,N′,N′-tetra(naphthalen-2-yl)benzidine, and mixtures thereof.

Materials for the hole transport layers 32 and 51, for the hole injection layer 31, for the electron transport layers 34 and 53 and for the electron injection layer 54 may be selected from known materials. For example, for the hole transport layers 32 and 51, one or more of the materials specified above with regard to the first and second hole-transporting layers may be selected. In addition, for the electron transport layers 34 and 53, one or more of the materials specified above with regard to the electron-transporting layer may be selected.

The charge carrier generation layer stack 40 contains, in the working example, an electron-transporting layer 41 comprising NET-18 as matrix material and NDN-26 as dopant and having a thickness of, for example, about 5 nm or 15 nm. The hole-transporting layer 43 has HAT-CN as its material and has a layer thickness, for example, of about 5 nm or 15 nm. The interlayer 42 has a thickness of about 4 nm and contains a polynuclear phthalocyanine derivative as its material, for example, selected from the compounds shown in the structural formulae IV, V, VI or VII.

An alternative embodiment of the charge carrier generation layer stack 40 is shown in FIG. 1b. This charge carrier generation layer stack has the first and second hole-transporting layers 43a and 43b and two interlayers 42 disposed between the electron-transporting layer 41 and the first hole-transporting layer 43a and between the first hole-transporting layer 43a and the second hole-transporting layer 43b. The first hole-transporting layer 43a may have HAT-CN as its material; the second hole-transporting layer 43b may have α-NPD, for example, as its material. The materials of the interlayers 42 and of the electron-transporting layer 41 correspond to those that have been mentioned in relation to FIG. 1a.

A further embodiment of the charge carrier generation layer stack 40 is shown in FIG. 1c. Again, only one interlayer 42 is present here, disposed between the electron-transporting layer 41 and the first hole-transporting layer 43a. In this embodiment, the second hole-transporting layer 43b disposed atop the first hole-transporting layer 43a may have p-doping having a proportion, for example, of less than 10% by volume, especially of less than 1% by volume, in the layer.

A component as shown in FIGS. 1a to 1c may also have further organic functional layer stacks, with a charge carrier generation layer stack 40 disposed between every two organic functional layer stacks and being configurable, for example, according to one of the embodiments as shown in FIGS. 1a to 1c.

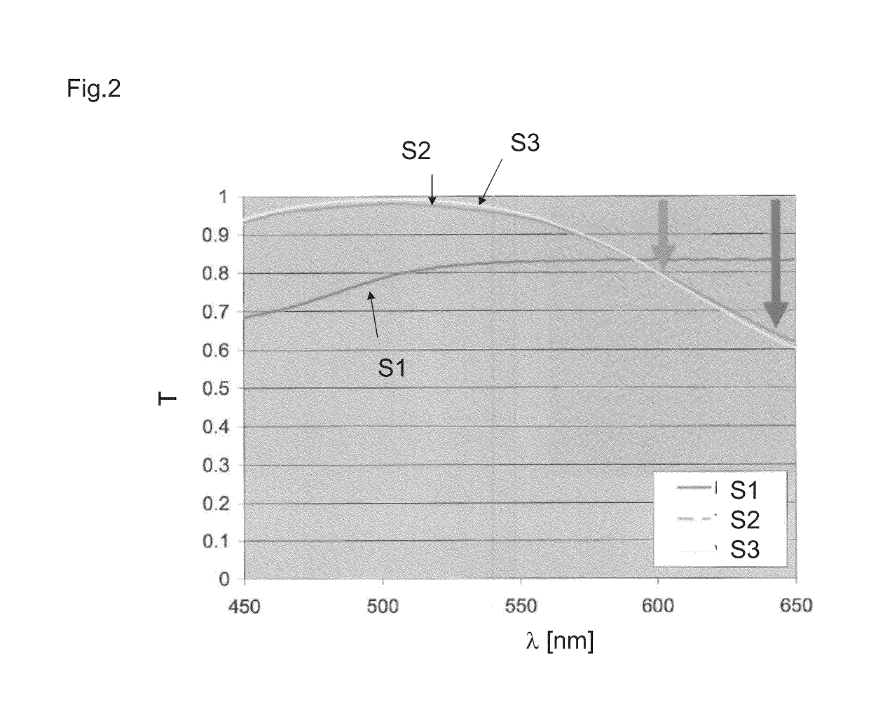

FIG. 2 shows an optical transmission spectrum in which the x axis shows the wavelength λ in nm and the y axis the transmission T. Example S1 is the transmission of the conventional material NET-39 of an interlayer 42; S2 and S3 show the transmission spectra of the mononuclear phthalocyanine derivatives VOPc (S2) and TiOPc (S3). It can be seen that the transmission is increased in the spectral range from about 450 nm to about 600 nm as a result of the use of mononuclear phthalocyanines, compared to the transmission of NET-39 in the same spectral range, which is attributable to the extended π electron system of the phthalocyanine derivative. This reduces the residual absorption in an organic light-emitting component, for example, an OLED, specifically in the yellow/green/blue region. Because of the further additional enlargement of the π electron system in polynuclear phthalocyanine derivatives, it is thus also possible to increase the corresponding transmission of the polynuclear phthalocyanine derivatives still further compared to the mononuclear phthalocyanine derivatives, specifically in the yellow/red region, because the intense absorption bands of low molecular weight species are shifted into the IR.

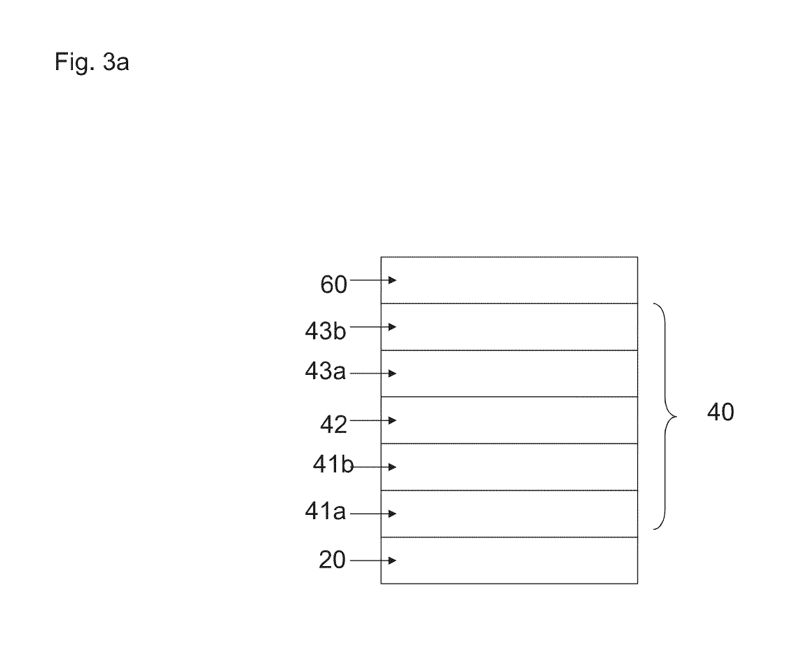

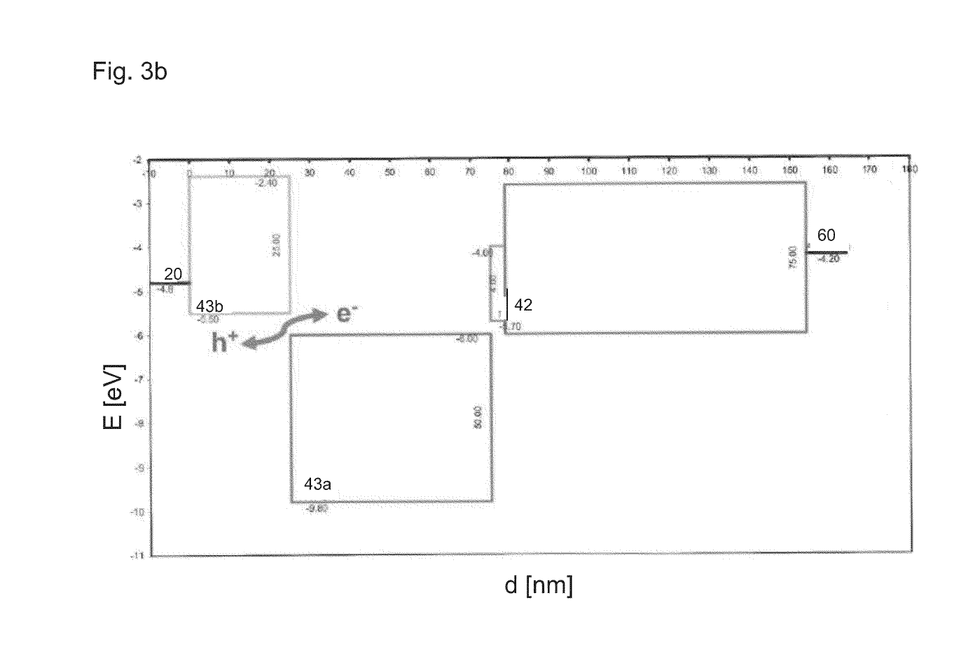

FIG. 3a shows a schematic side view of a charge carrier generation layer stack 40 disposed between a first electrode 20 and a second electrode 60. In this specific example, the first electrode 20 is formed from ITO and glass, the first electron-transporting layer 41a is formed from undoped NET-18, and the second electron-transporting layer 41b contains NET-18 doped with NDN-26. The interlayer 42 is formed from TiOPc, the first hole-transporting layer 43a from HAT-CN, the second hole-transporting layer 43b from α-NPD and the second electrode 60 from aluminum.

On the basis of this structure, FIG. 3b shows, in an energy level diagram, the energetic ratios of the materials relative to one another. The diagram shows the thickness d in nm on the x axis and the energy E in electron volts on the y axis. The charge separation or the generation of an electron and a hole takes place at the α-NPD/HAT-CN interface, since the LUMO of HAT-CN is below the HOMO of α-NPD. The hole from the α-NPD is transported to the left to the adjacent emission zone, while the electron from HAT-CN is conducted to the right to the next emission zone via the interlayer 42 and the electron-transporting layers 41a and b. For electron transport over the high energy barrier between HAT-CN and NET-18, high n-doping of NET-18 is important. High n-doping in NET-18 leads to significant band distortion and consequently to a narrow energy barrier which is easy for the electrons to tunnel through.

When polynuclear phthalocyanine derivatives, for example, the compounds shown in the structural formulae IV to VII, are used rather than mononuclear phthalocyanines, it is possible to increase the tunneling current with the same voltage and for the charge carrier generation layer stack to remain stable, meaning that a high voltage stability is recorded in the stress test at high temperature. Moreover, transmission is advantageously increased in the yellow/red spectral region.

Because it is possible for the enlarged polynuclear phthalocyanine derivatives to be vapor-deposited as a coherent layer, the hole-transporting layer 43, for example, the HAT-CN layer, can be separated even more effectively from the very reactive, possibly n-doped electron-transporting layer 41.

By means of absorption spectra of various compounds from which interlayers 42 can be formed, it is possible to compare the absorption properties thereof.

If, for example, the absorption spectrum of ZnPc (III) is compared with metal-free H₂Pc (Ma), a slightly lowered absorption is observed, especially in the range between 300 nm and 450 nm, for ZnPc compared to H₂Pc. In addition, H₂Pc has two characteristic transitions of the π electron system at about 650 nm and 700 nm, whereas ZnPc has one characteristic transition between the two transitions of H₂Pc.

The ZnPc-ZnPc shown in structural formula V in toluene, compared to H₂Pc-H₂Pc shown in structural formula IV, likewise exhibits lowered absorption in the range from 300 nm to 800 nm. The characteristic transitions of the π electron system of H₂Pc-H₂Pc are both between 600 nm and 650 nm; the characteristic transition of ZnPc-ZnPc is in between.

Comparison of the absorption characteristics of a linear trinuclear phthalocyanine derivative (VI) compared to a trinuclear phthalocyanine derivative fused at right angles (VII), with both phthalocyanine derivatives containing Zn, shows that the linear variant exhibits lower absorption in the range, for instance, of 400 to 800 nm than the variant having right-angled fusion and additionally has a characteristic transition of the π electron system at about 950 nm, whereas the right-angled variant has two transitions at about 850 nm and 900 nm.

The invention is not restricted to the working example by the description with reference thereto. Instead, the invention encompasses every new feature and every combination of features, which especially includes every combination of features in the claims, even if this feature or this combination itself is not specified explicitly in the claims or working examples.

1-15. (canceled)

16. An organic light-emitting component comprising:
a substrate;
a first electrode atop the substrate;
a first organic functional layer stack atop the first electrode;
a charge carrier generation layer stack atop the first organic functional layer stack, wherein the charge carrier generation layer stack comprises a hole-transporting layer, an electron-transporting layer and an interlayer, and wherein the interlayer includes a polynuclear phthalocyanine derivative;
a second organic functional layer stack atop the charge carrier generation layer stack; and
a second electrode atop the second organic functional layer stack.

17. The component according to claim 16, wherein the polynuclear phthalocyanine derivative contains a metal or a metal compound.

18. The component according to claim 17, wherein the metal or metal compound comprises a material selected from the group consisting of Cu, Zn, Co, Al, Ni, Fe, SnO, Mn, Mg, VO and TiO.

19. The component according to claim 16, wherein the polynuclear phthalocyanine derivative is metal-free.

20. The component according to claim 16, wherein the polynuclear phthalocyanine derivative is a dinuclear phthalocyanine derivative.

21. The component according to claim 16, wherein the polynuclear phthalocyanine derivative is a tri- or tetranuclear phthalocyanine derivative.

22. The component according to claim 21, wherein the tri- or tetranuclear phthalocyanine derivative has phthalocyanine derivatives fused in a linear or right-angled manner.

23. The component according to claim 16, wherein the interlayer has a thickness between 1 nm and 50 nm.

24. The component according to claim 16, wherein the polynuclear phthalocyanine derivative is obtained by fusion by benzene rings of two or more mononuclear phthalocyanine units.

25. The component according to claim 16, wherein the hole-transporting layer comprises a first hole-transporting layer and a second hole-transporting layer, the first hole-transporting layer being disposed atop the electron-transporting layer and the second hole-transporting layer atop the first hole-transporting layer.

26. The component according to claim 25, wherein the interlayer is disposed between the electron-transporting layer and the first hole-transporting layer and/or between the first hole-transporting layer and the second hole-transporting layer.

27. The component according to claim 25, wherein the hole-transporting layer is undoped or p-doped.

28. The component according to claim 25, wherein the first and second hole-transporting layers are undoped or independently p-doped.

29. The component according to claim 16, wherein the electron-transporting layer comprises and n-doped layer.

30. The component according to claim 29, wherein the hole-transporting layer is undoped or p-doped.

31. The component according to claim 16, wherein the component comprises an organic light-emitting diode.

32. A method for producing an organic light-emitting component, the method comprising:
forming a first organic functional layer stack over a first electrode disposed atop a substrate;
forming an electron-transporting layer atop the first organic functional layer stack;
forming an interlayer atop the electron-transporting layer, wherein forming the interlayer comprises applying a polynuclear phthalocyanine derivative;
forming a hole-transporting layer atop the interlayer;
forming a second organic functional layer stack atop the hole-transporting layer; and
forming a second electrode atop the second organic functional layer stack.

33. The method according to claim 32, wherein forming the hole-transporting layer atop the interlayer comprises forming a second hole-transporting layer atop the interlayer, the method further comprising forming a first hole-transporting layer atop the electron-transporting layer, the interlayer being formed atop the first hole-transporting layer.

34. The method according to claim 32, wherein the polynuclear phthalocyanine derivative is applied by vapor deposition or as a solution.

35. An organic light-emitting component comprising:
a substrate;
a first electrode atop the substrate;
a first organic functional layer stack atop the first electrode;
a charge carrier generation layer stack atop the first organic functional layer stack, wherein the charge carrier generation layer stack comprises a hole-transporting layer, an electron-transporting layer and an interlayer, and wherein the interlayer includes a polynuclear phthalocyanine derivative that contains a metal or a metal compound selected from the group consisting of Cu, Co, Al, Ni, Fe, SnO, Mn, Mg and VO;
a second organic functional layer stack atop the charge carrier generation layer stack; and
a second electrode atop the second organic functional layer stack.
